(19) United States
(12) Patent Application Publication
(10) Pub. No.: US 2024/0234358 A1
(43) Pub. Date: Jul. 11, 2024

(54) SEMICONDUCTOR PACKAGE HAVING DUMMY SOLDERS AND MANUFACTURING METHOD THEREOF

(71) Applicant: Samsung Electronics Co., Ltd., Suwon-si (KR)

(72) Inventor: JUNHO LEE, Suwon-si (KR)

(21) Appl. No.: 18/226,065

(22) Filed: Jul. 25, 2023

(30) Foreign Application Priority Data
Jan. 11, 2023 (KR) 10-2023-0004217

(51) Int. Cl. H01L 23/00; H01L 23/498

(52) U.S. Cl. CPC H01L 24/14; H01L 23/49811; H01L 24/05; H01L 24/11; H01L 24/13; H01L 24/16; H01L 24/81; H01L 24/04; H01L 24/32; H01L 24/73; H01L 25/18; H01L 2224/0401; H01L 2224/05073; H01L 2224/05124; H01L 2224/05147; H01L 2224/05562; H01L 2224/11334; H01L 2224/11849; H01L 2224/13013; H01L 2224/13014; H01L 2224/13016; H01L 2224/13082; H01L 2224/13147; H01L 2224/1403; H01L 2224/14051; H01L 2224/14131; H01L 2224/14155; H01L 2224/14177; H01L 2224/14505; H01L 2224/14517; H01L 2224/16146; H01L 2224/16227; H01L 2224/32225; H01L 2224/73204; H01L 2224/81815

(57) ABSTRACT

The present disclosure provides a semiconductor package having a dummy solder and a manufacturing method thereof. The solder bump array is disposed on one surface of the semiconductor package, and a dummy solder is disposed point-symmetrically about a center of the solder bump array. The solder bumps have a first melting point, and the dummy solder has a second melting point lower than the first melting point so that the dummy solder melts before the solder bumps to generate a force in a direction in which the solder bump contacts the connection terminal of the external device by surface tension in a soldering process.

### CROSS-REFERENCE TO RELATED APPLICATION

This application claims priority to and the benefit of Korean Patent Application No. 10-2023-0004217 filed in the Korean Intellectual Property Office on Jan. 11, 2023, the entire contents of which are incorporated herein by reference.

### BACKGROUND

### 1. Field

The present disclosure relates to a semiconductor package and a manufacturing method thereof, and more specifically, to a semiconductor package having improved solder connections and a manufacturing method thereof.

### 2. Description of the Related Art

Soldering is widely used to realize electrical connection as well as physical bonding between various types of devices, such as between chips, between a chip and a chip carrier, and between a chip carrier and a system board.

In a soldering process, when a certain amount of solder material (usually solder paste) is first disposed on a plurality of connection terminals provided on one surface of a first device, and when a certain temperature is applied thereto, the solder material becomes a spherical shape due to surface tension. This is called a solder ball or solder bump, and a plurality of solder bumps disposed on one surface is called a solder bump array.

After aligning the first device to a second device so that the solder bump array contacts a plurality of connection terminals of the second device, a reflow process is performed. In the reflow process, each solder bump is exposed to a temperature that is higher than a melting point in a state of being in contact with each connection terminal of the second device. Then, the bump is changed to a liquid state, wets each connection terminal, and then is cooled, so that electrical connection as well as physical coupling are realized between the connection terminal of the first device and the connection terminal of the second device.

As described above, in the process of providing the solder bump array, the solder bumps are provided by disposing a certain amount of solder material on the connection terminal and then applying heat at a certain temperature. In this process, an intermetallic compound (IMC) layer is provided between the solder material and the connection terminal. Properly controlled growth of the IMC layer is not problematic, but when the IMC layer excessively grows, protruding portions may be formed on a surface of the solder bump.

Meanwhile, in the process of applying heat of a certain temperature to provide the solder bump array, a void may be formed inside the solder bump. As the void is pushed out of a surface thereof, a pitted portion may be formed on the surface of the solder bump.

In addition to the conditions mentioned above, an uneven surface of the solder bump may be formed due to various causes. The uneven surface of the solder bump may cause connection failure in the reflow process for bonding.

A portion protruding more than the surrounding normal solder bumps causes unstable contact with the connection terminals of the surrounding normal solder bumps. In addition, the pitted portion of the uneven surface causes unstable contact with the connection terminal of the corresponding solder bump. The unstable contact may cause connection failure during the reflow process.

As described above, when the surfaces of some of the solder bumps in the solder bump array are uneven, heights thereof in contact with the connection terminals of the solder bumps in the solder bump array are uneven, which causes non-uniform contact with the connection terminals.

As the solder bump array is miniaturized and a mounting density increases, the possibility of a connection failure increases even when there is only a small unevenness. With high integration, the number of connection terminals of a single semiconductor chip is significantly increased, and accordingly, it is necessary to dispose finer solder bumps at a higher density. However, the miniaturization and high density of the solder bumps further increase the possibility of poor connection due to minute surface irregularities.

### SUMMARY

Embodiments of the present disclosure have been made in an effort to suppress connection failure due to a solder bump having an uneven surface.

According to a first aspect of the present disclosure, a semiconductor package is provided. The semiconductor package includes: a main body including at least one semiconductor chip; a plurality of connection terminals provided on one surface of the main body; a solder bump array disposed on each of the connection terminals and including a plurality of solder bumps that electrically connect each of the connection terminals to a connection terminal of another device by a soldering process; and at least one dummy solder disposed on one surface of the main body and disposed point-symmetrically about a center of the solder bump array, wherein the solder bumps have a first melting point, and the dummy solder has a second melting point lower than the first melting point so that the dummy solder melts before the solder bump to generate a force in a direction in which the solder bumps contact the connection terminals of the another device by surface tension in the soldering process.

The at least one dummy solder may be disposed at the outside of the solder bump array.

One surface of the main body may have a quadrangular shape, and the at least one dummy solder may include a plurality of dummy solders disposed at each of the four corners of the one surface of the main body or at each of the four sides of the one surface of the main body.

At least one dummy solder may include a plurality of dummy solders having the same shape and size as the solder bump.

Each of the connection terminals may include: a connection pad and a conductive metal post protruding from the connection pad, and each of the solder bumps may be disposed on each metal post; and a plurality of dummy connection terminals having the same structure as the connection terminal may be disposed on one surface of the main body at a position corresponding to the plurality of dummy solders, and each of the plurality of dummy solders may be disposed on a respective metal post of the dummy connection terminals.

A dummy solder of the plurality of dummy solders may have a different shape or size from that of the solder bumps, and a maximum height thereof from the one surface of the main body may be the same as those of the solder bumps.

The at least one dummy solder may have a ball or line shape.

The at least one dummy solder may include at least one solder bump having the same shape and size as the solder bump and at least one solder bump having a different shape or size than the solder bump.

The main body may further include a substrate or an interposer on one surface of which the at least one semiconductor chip is mounted and on the other surface of which the plurality of solder bumps and the plurality of dummy solders are disposed.

One surface of the main body may be one surface of the at least one semiconductor chip.

The first melting point may be 210° C. or more, and the second melting point may be 190° C. or less. The dummy solder may be made of Sn—Bi—X, where X may be Ag or Fe. A Bi content may be 35 to 40 wt %, and an Ag or Fe content may be 6 wt % or less.

According to a second aspect of the present disclosure, a semiconductor package is provided. The semiconductor package includes: at least one semiconductor chip; a chip carrier to which the semiconductor chip is bonded to a first surface thereof; and a resin mold that seals the at least one semiconductor chip and the first surface with a resin material, wherein the chip carrier includes a redistribution layer, a plurality of first connection terminals on the first surface for connection with the semiconductor chip, and a plurality of second connection terminals on a second surface opposite to the first surface for connection with another device; the plurality of first connection terminals are electrically connected to terminals of the semiconductor chip by solder bumps; each of the second connection terminals includes a connection pad connected to the redistribution layer and a metal post disposed on the connection pad, and a solder bump having a diameter of 10 to 30 μm is disposed on each metal post; the chip carrier includes at least two dummy solders at the outside of the plurality of second connection terminals on the second surface; and the solder bumps have a first melting point, and the dummy solder has a second melting point lower than the first melting point so that the dummy solder melts before the solder bump to generate a force in a direction in which the solder bumps contact the connection terminals of the another device by surface tension in the soldering process.

The chip carrier may further include a plurality of dummy connection terminals having the same structure as the second connection terminal at the outside of the plurality of second connection terminals on the second surface, and the at least two dummy solders may have the same size and shape as the solder bumps and be provided on metal posts of the dummy connection terminals.

According to a third aspect of the present disclosure, a manufacturing method of a semiconductor package is provided. The manufacturing method of the semiconductor package includes: attaching at least one semiconductor chip to a first surface of a chip carrier and providing a plurality of connection terminals for electrical connection with another device on a second surface opposite to the first surface, wherein each of the connection terminals includes a connection pad and a metal post disposed on the connection pad; disposing a first solder material onto the second surface so as to be point symmetrical about a center of the plurality of connection terminals; providing a plurality of dummy solders by performing a first reflow process on the first solder material with a first maximum temperature; disposing a second solder material onto metal posts of the plurality of connection terminals; and providing a plurality of solder bumps by performing a second reflow process on the second solder material with a second maximum temperature, wherein a melting point of the first solder material is lower than that of the second solder material, and the first maximum temperature is lower than the second maximum temperature.

The providing of the plurality of connection terminals may include: further providing a plurality of dummy connection terminals disposed point-symmetrically about the center of the plurality of connection terminals on the second surface, and the plurality of dummy connection terminals have the same structure as the plurality of connection terminals; the disposing of the first solder material on one surface of the package main body may include: covering the second surface with a first mask having openings at positions corresponding to the plurality of dummy connection terminals; and disposing the first solder material on the metal posts of the dummy connection terminals through the openings of the first mask, and the disposing of the second solder material onto the metal posts of the plurality of connection terminals may include: covering the second surface with a second mask having openings at positions corresponding to the metal posts of the plurality of connection terminals; and disposing the second solder material on the metal posts of the connection terminals through the openings of the second mask.

The disposing of the first solder material on the second surface may include disposing the first solder material in a ball or line shape on the second surface so as to be disposed point-symmetrically about the center of the plurality of connection terminals.

The plurality of dummy solders may be disposed at the outside of the plurality of solder bumps.

According to the embodiments of the present disclosure, at least one dummy solders having a relatively low melting point is disposed point-symmetrically about a center of the solder bumps, so that the dummy solder melts before the solder bumps in a reflow process for bonding between two devices, thereby generating a force in a direction in which connection terminals of the two devices are attracted to each other by surface tension. By this force, the solder bumps contact the connection terminals under appropriate pressure, thereby realizing a more uniform connection and reducing connection defects during the reflow process.

### BRIEF DESCRIPTION OF THE DRAWINGS

FIG. 1 illustrates a schematic structure diagram of a semiconductor package to which embodiments of the present disclosure may be applied.

FIG. 2 illustrates a structure of a solder bump to which embodiments of the present disclosure may be applied.

FIG. 3A to FIG. 3D schematically illustrate various examples of disposition of dummy solders according to an embodiment of the present disclosure.

FIG. 4A to FIG. 4C illustrate operations of dummy solders according to an embodiment of the present disclosure.

FIG. 5 schematically illustrates an example of a semiconductor package having dummy solders having a different shape or size from a solder bump array according to another embodiment of the present disclosure.

FIG. 6 schematically illustrates an example of disposition of dummy solders in the embodiment of FIG. 5.

FIG. 7 schematically illustrates an example of a semiconductor package having dummy solders having a different shape or size from a solder bump array according to another embodiment of the present disclosure.

FIG. 8A and FIG. 8B schematically illustrate examples of disposition of dummy solders in the embodiment of FIG. 7.

FIG. 9 schematically illustrates a cross-sectional view of a structure of a semiconductor package according to another embodiment of the present disclosure.

FIG. 10 schematically illustrates a cross-sectional view of a structure of a semiconductor package according to another embodiment of the present disclosure.

FIG. 11 schematically illustrates a cross-sectional view of a structure of a semiconductor package according to another embodiment of the present disclosure.

FIG. 12A and FIG. 12B schematically illustrate a manufacturing method of a semiconductor package according to an embodiment of the present disclosure.

FIG. 13 schematically illustrates a manufacturing method of a semiconductor package according to another embodiment of the present disclosure.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description may be omitted, and identical or similar constituent elements throughout the specification may be denoted by the same reference numerals.

Further, in the drawings, the size and thickness of each element are arbitrarily illustrated for ease of description, and the present disclosure is not necessarily limited to those elements illustrated in the drawings. In the drawings, the thicknesses of layers, films, panels, regions, areas, etc., are exaggerated for clarity.

In addition, in the drawings, solder bumps, connection terminals, and dummy bumps are enlarged and exaggerated compared to other elements in order to better show their structures.

It will be understood that when an element such as a layer, film, region, area or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion and does not necessarily mean disposed on the upper side of the object portion based on a gravitational direction. The term “contact,” “contacting,” “contacts,” or “in contact with,” as used herein, refers to a direct connection (i.e., touching) unless the context clearly indicates otherwise.

In addition, unless explicitly described to the contrary, the word “comprise” and variations such as “comprises” or “comprising” will be understood to imply the inclusion of stated elements but not the exclusion of any other elements.

The following description may use the term “point-symmetrically” to describe the orientation of objects. Point-symmetrically indicates that the objects are arranged to have point symmetry in which a point has a matching point that is the same distance from a central point but in an opposite direction.

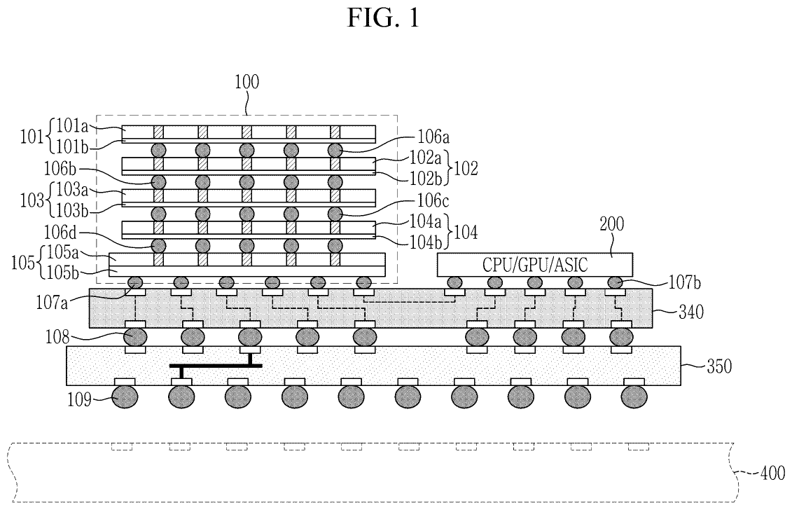

FIG. 1 illustrates a schematic structure diagram of a semiconductor package to which embodiments of the present disclosure may be applied. The semiconductor package is also referred to as a 2.5D package. A main body of the semiconductor package includes components that are coupled together and that make up the semiconductor package. For example, the main body can include a semiconductor chip and supporting structures such as a substrate, encapsulant, and/or an interposer.

A memory chip stack 100 and a processor chip 200 are mounted on one surface of an interposer 340 made of silicon or glass. The memory chip stack 100 includes first to fourth memory chips 101, 102, 103, and 104 that are vertically stacked, a logic chip 105, and a first type of solder bumps 106a, 106b, 106c, and 106d connecting respective chips. In some embodiments, the semiconductor chip stack 100 may be a high bandwidth memory (HBM) chip. The first memory chip 101 may include a first layer 101a and a second layer 101b, the first layer 101a may include through silicon vias (TSV), generally described as through substrate vias, and the second layer 101b may include a plurality of vias (not shown) and a plurality of metal wires (not shown). The second to fourth memory chips 102, 103, and 104 and the logic chip 105 also include first layers 102a, 103a, 104a, and 105a and second layers 102b, 103b, 104b, and 105b, respectively. Although not shown, each of the first type of solder bumps 106a, 106b, 106c, and 106d is disposed between connection terminals provided on surfaces of both chips facing each other, thereby realizing electrical connection between the chips.

One surface of the second layer 105b of the logic chip 105 is mounted on one surface of the interposer 340 through a second type of solder bumps 107a. The processor chip 200 is also mounted on the same surface of the interposer 340 through the second type of solder bumps 107b. The processor chip 200 may be, for example, a central processing unit (CPU), a graphics processing unit (GPU), or an accelerated processing unit (APU).

Connection terminals that the solder bumps contact are provided on both the first surface and a second surface of the interposer 340, and wires connecting the connection terminals are included therein. Although briefly illustrated in FIG. 1, the interposer 340 may include a redistribution layer. A third type of solder bumps 108 are disposed on the second surface of the interposer 340. The third type of solder bumps 108 connect the interposer 340 and a package substrate 350. Connection terminals provided on a first surface of the package substrate 350 are in contact with the third type of solder bumps 108. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

A fourth type of solder bumps 109 are provided on connection terminals provided on a second surface of the package substrate 350. The second surface of the package substrate may hereafter be referred to as an “outer surface.” When the semiconductor package is mounted on an external device 400, the fourth type of solder bumps 109 are connected to connection terminals of the external device 400. The external device 400 may be, for example, a system board.

Bonding between two devices by using solder bumps realizes not only an electrical connection but also a physical coupling, and solder bumps may be used for bonding between various types of devices. Referring to FIG. 1 as an example, the first type of solder bumps 106a, 106b, 106c, and 106d are used for chip-to-chip bonding, the second type of solder bumps 107a and 107b are used for bonding between the chip and the interposer, the third type of solder bumps 108 are used for bonding between the interposer and the package substrate, and the fourth type of solder bumps 109 are used for bonding between a package substrate and another device.

With the high integration of semiconductors and the miniaturization of wires, the size and pitch of the solder bumps for bonding between devices are also decreasing. Generally, the size/pitch of the first type of solder bumps 106a, 106b, 106c, and 106d is equal to or smaller than that of the second type of solder bumps 107a and 107b, but is not limited thereto. In addition, the size/pitch of the second type of solder bumps 107a and 107b is equal to or smaller than that of the third type of solder bumps 108. Similarly, the size/pitch of the third type of solder bumps 108 is equal to or smaller than that of the fourth type of solder bumps 109.

In the embodiments of the present disclosure, at least one dummy solder, preferably a plurality of dummy solders are disposed point-symmetrically about a center of a solder bump array including a plurality of solder bumps. The at least one dummy solder has a lower melting point than the solder bumps that are disposed together on the same surface.

In the following embodiments, a plurality of dummy solders are disclosed, but one dummy solder may be used. For example, a dummy solder in a shape of one continuous line may be disposed to passing through the center of the solder bump array or to surround the perimeter of the solder bump array.

According to some embodiments of the present disclosure, the disposition of the dummy solder may be applied between chips together with the first type of solder bumps 106a, 106b, 106c, and 106d. In these embodiments, at least one dummy solder may be provided with the first type of solder bumps on one surface of the chip. In this case, the at least one dummy solder is disposed point-symmetrically about the center of the first type of solder bumps on one surface of the chip.

According to some embodiments of the present disclosure, the at least two dummy solders can be arranged such that a center point of the at least two dummy solders is aligned with a center point of the first type of solder bumps. For example, using an XY coordinate system, the center point of a group of objects, such as the at least two dummy solders or the first type of solder bumps, may be found by summing the X component of each object divided by the number of objects to find the X component of the center point and summing the Y component of each object divided by the number of objects to find the Y component of the center point. The at least two dummy solders can be arranged such that the X and Y components of the center point are the same as the X and Y components of the center point of the first type of solder bumps.

According to some embodiments of the present disclosure, the disposition of the dummy solder may be applied between the logic chip 105 and the interposer 340, and between the processor chip 200 and the interposer 340 together with the second type of solder bumps 107a and 107b. In these embodiments, at least one dummy solder may be provided on one surface of the logic chip 105 together with second type of solder bumps 107a. In addition, at least one dummy solder may be provided on one surface of the processor chip 200 together with the second type of solder bumps 107b. In this case, the at least one dummy solder is disposed point-symmetrically about the center of the second type of solder bumps 107a on one surface of the logic chip 105. In addition, the at least one dummy solder is disposed point-symmetrically about the center of the second type of solder bumps 107b on one surface of the processor chip 200.

According to some embodiments of the present disclosure, the disposition of the dummy solder may be applied between the interposer 340 and the package substrate 350 together with the third type of solder bumps 108. At least one dummy solder is disposed point-symmetrically about the center of the third type of solder bumps 108 on one surface of the interposer 340.

According to some embodiments of the present disclosure, at least one dummy solder may be disposed together with the fourth type of solder bumps 109 on the outer surface of the package substrate 350. At least one dummy solder is disposed point-symmetrically about the center of the fourth type of solder bumps 109.

As described above, in the 2.5D package shown in FIG. 1, the disposition of the dummy solder may be applied to bonding between various devices, but in some embodiments, it may be preferable to apply the dummy solder on the outer surface of the package substrate 350 among others. Generally, a semiconductor package completed by a package manufacturing process may be moved to another location and mounted on a system board for manufacturing an information device such as a computer or a smart phone at the other location. In this case, the solder bumps provided on the outer surface of the package substrate 350 through the reflow process are melt-bonded to the corresponding connection terminals of the system board. The semiconductor package may be sealed by a resin mold such as epoxy except for the outer surface of the package substrate 350. The solder bumps 109 provided on the outer surface of the package substrate 350 may not be protected by the resin mold and may be affected by the external environment. In addition, the semiconductor package may be moved from a package manufacturing site to a system manufacturing site. The system manufacturing process may have relatively lower precision than the package manufacturing process. The disposition of the dummy solder may contribute to reducing the probability of occurrence of connection defects caused by the uneven surfaces of some of the solder bumps 109 and increasing yield in the system manufacturing process.

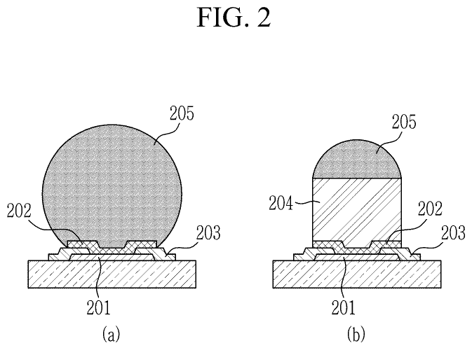

In the embodiments of the present disclosure, the solder bumps are provided on connection terminals on one surface of one device prior to bonding to another device. FIG. 2 illustrates two typical types of solder bumps provided on the connection terminals as an example of solder bumps. A metal pad 201 made of one metal such as copper (Cu) or aluminum (Al) or of an alloy of these metals is provided on a chip, and an under bump metallurgy (UBM) layer 202 thereon penetrates a passivation layer 203 to electrically contact the metal pad 201.

In FIG. 2 (a), a solder bump 205 is directly provided on the UBM layer 202, while in FIG. 2 (b), the solder bumps 205 are provided on a metal post 204 with the metal post 204 interposed between the UBM layer 202. The metal post 204 may be a copper (Cu) pillar. The solder bump 205 may be a normal solder bump 310 or a dummy solder 320 in an embodiment to be described later.

In the embodiments of the present disclosure, the solder bump may have one of the two shapes shown in FIG. 2, but embodiments of the inventive concept are not limited thereto, and when a material with a melting point lower than that of the connection terminal is used for bonding between the connection terminals of the two devices, the material may correspond to the solder bump in the embodiments of the present disclosure.

Preferably, a maximum height of the dummy solder is set equal to a maximum height of solder bumps provided together with the dummy solder. When the maximum heights are the same, the size or shape of the dummy solder may be the same as or different from that of the solder bumps. However, when the size and shape of the dummy solder are set to be the same as those of the solder bumps, the dummy solder and the solder bumps may be provided in the same process, so the process of providing the dummy solder may be simplified, and it is relatively easy to set the heights of the dummy solder and solder bumps to be the same. Accordingly, in the embodiment of FIG. 1, each dummy solder disposed together with the solder bumps of each group may be provided to have the same size and shape as the solder bumps of each group.

When the dummy solder is provided to have the same size and shape as the solder bumps, it is convenient to provide dummy connection terminals having the same structure as connection terminals provided under the solder bumps under the dummy solder. When the connection terminals of the solder bumps include connection pads and metal posts, it is convenient that the dummy connection terminals also include connection pads and metal posts. The dummy connection terminal refers to a terminal that does not communicate with other components in a manner that affects the operation of the semiconductor package. The dummy connection terminal may be electrically isolated or may be a terminal connected to the ground and/or not electrically connected between any circuit components that communicate with each other.

Generally, the metal posts are used for solder bump arrays in which finer diameters and pitches are required. Accordingly, the effect of the present disclosure may be maximized by applying a dummy solder to a semiconductor package having a solder bump array using a metal post. In an example, the disposition of the dummy solder according to the embodiments of the present disclosure may be applied to a micro pillar grid array (mPGA) package. In some embodiments, the diameters of the solder bump and the dummy solder are 10 to 30 μm. When the solder bump having this diameter is used, an effect of reducing connection defects due to disposition of the dummy solder increases because the influence of the uneven surface of the solder bump is significant.

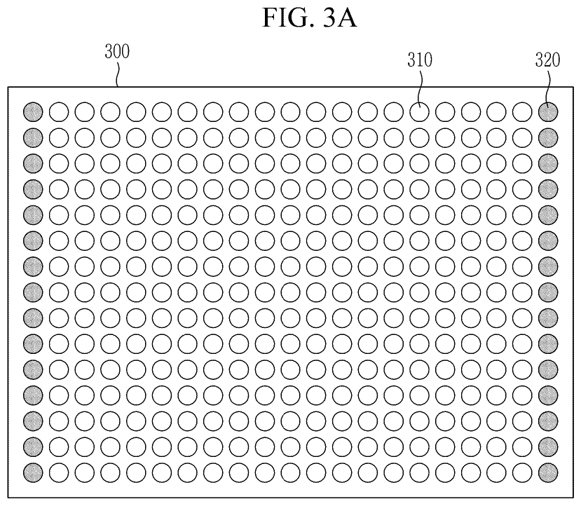

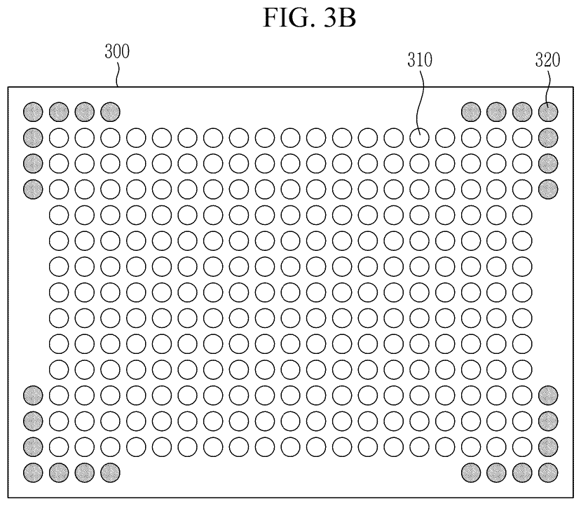

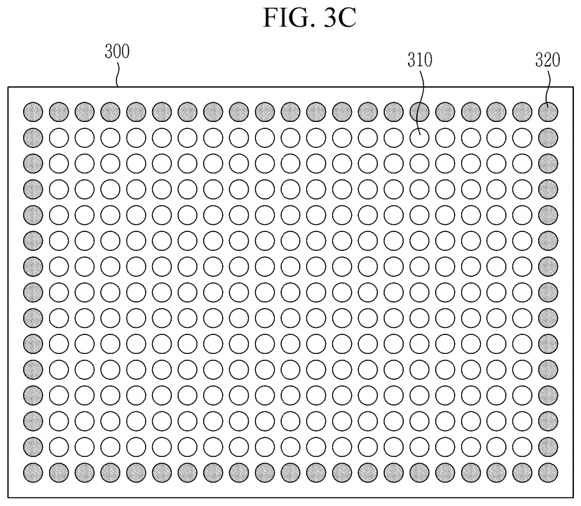

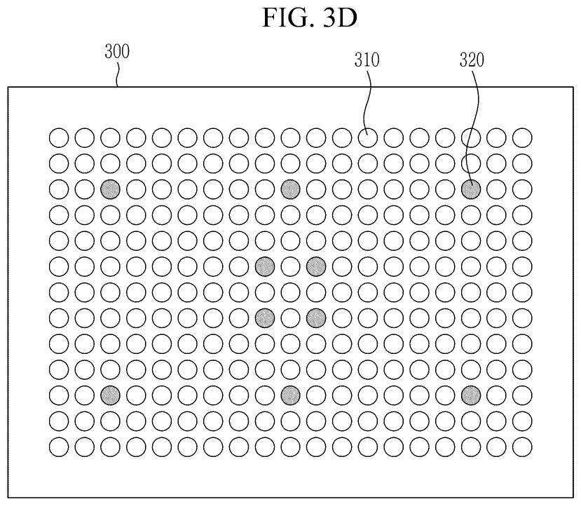

At least two dummy solders are preferably disposed point-symmetrically about the center of the solder bump array to apply a uniform pressure to each solder bump. FIG. 3A to FIG. 3D illustrate examples in which dummy solders are disposed point-symmetrically on a semiconductor package having a quadrangular main body. In these examples, the dummy solder has the same shape and size as the solder bumps. However, it should be understood that the dummy solder may have a different shape or size from that of the solder bumps.

In FIG. 3A, a solder bump array 310 is provided on one surface of a semiconductor package 300, and dummy solders 320 are disposed at left and right sides of the drawing. The semiconductor package 300 may be, for example, the 2.5D package of FIG. 1, but is not limited thereto. The semiconductor package 300 may be the memory chips 101, 102, 103, and 104 or the logic chip 105 of FIG. 1, or the semiconductor package 300 may be the memory chip stack 100, or the semiconductor package 300 may include the interposer 340, the memory chip stack 100 stacked thereon, and the processor chip 200.

In FIG. 3B, the dummy solders 320 are disposed at four corners of the solder bump array 310.

In FIG. 3C, the dummy solders 320 are disposed to surround a periphery of the solder bump array 310.

In FIG. 3A to FIG. 3C, the dummy solders 320 are disposed at the outside of the solder bump array 310, but as shown in FIG. 3D, the dummy solders 320 may be disposed at the inside of the solder bump array 310. Although not shown, the dummy solder 320 may be disposed at the center of the solder bump array. In addition, those skilled in the art will understand that the dummy solders 320 may be disposed both inside and outside the solder bump array 310.

Generally, bonding using the solder bumps (also referred to as ‘soldering’) is realized through a process of disposing a solder material on a connection terminal provided on a surface of one of two devices to be bonded, a process of applying heat so that the solder material melts and is bonded to the connection terminal (referred to as a ‘reflow process for providing bumps’), a process of aligning two devices so that the solder bumps contact a connection terminal provided on a surface of the other of the two devices to be bonded, and a process of applying heat so that the solder bumps are melted and bonded to connection terminals provided on a surface of another device (also referred to as ‘reflow for bonding’).

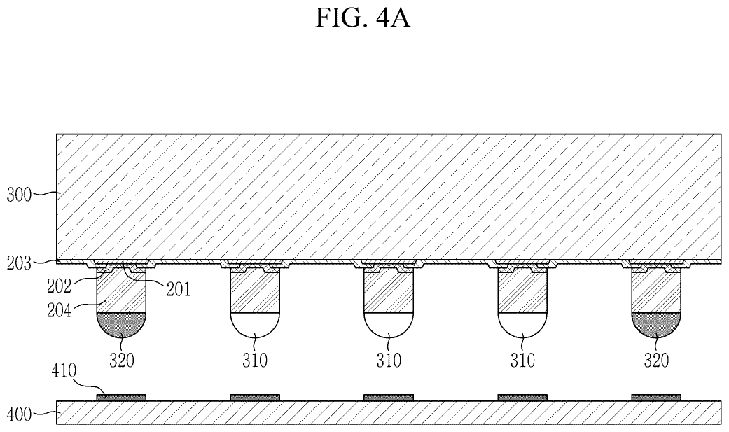

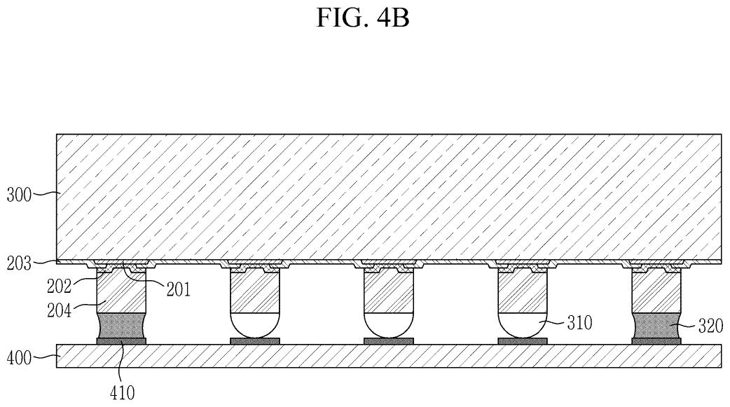

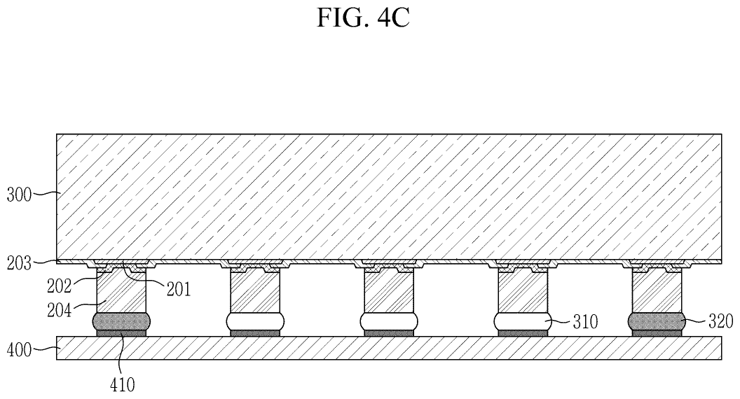

FIG. 4A to FIG. 4C illustrate drawings for explaining operations of the dummy solders in the reflow process for bonding. As shown in FIG. 4A, the metal pads 201 are provided on one surface of the semiconductor package 300, and the UBM layers 202 pass through the passivation layer 203 to be connected to the metal pads 201. The metal posts 204 are provided on the UBM layers 202, and the solder bumps 310 and the dummy solders 320 are provided on the metal posts 204. In the present embodiment, the solder bumps and the dummy solders have the same shape and size.

The semiconductor package 300 is aligned to an external device 400 so that the solder bumps 310 and the dummy solders 320 correspond to connection terminals 410 provided on one surface of the external device 400 such as a system board. The reflow process for bonding the semiconductor package 300 to the external device 400 may then be performed as described in relation to FIGS. 4B and 4C.

FIG. 4B illustrates a state in which the dummy solders 320 are melted into a molten liquid state while the solder bumps 310 have not reached their melting point. The solder bumps 310 remain in a solid state and the melted dummy solders 320 contact the connection terminals 410 of the external device 400.

Because the dummy solders 320 have a lower melting point than the solder bumps 310, a distance between the semiconductor package 300 and the external device 400 is not affected by the dummy solders 320 in the molten liquid state since the solder bumps 310 have not yet been melted. The dummy solders 320 in the molten liquid state contact and wet the connection terminals 410 generating a surface tension that works to minimize the surface area of the molten liquid of the dummy solders 320. The surface tension results in a net force pulling the connection terminals 410, and this force attracts the semiconductor package 300 and the external device 400 to each other.

The force caused by the surface tension of the dummy solders 320 in the molten liquid state causes the solder bumps 310 and the connection terminals 410 to come into contact with each other more strongly compared to if there were no dummy solders 320. When there is a solder bump having a protrusion on a surface thereof, the protrusion contacts the connection terminal 410 with a greater force than other solder bumps in the vicinity since the protrusion contacts the connection terminal first, and the protrusion is quickly melted so that the other solder bumps in the vicinity may normally contact the connection terminals. In addition, when there is a solder bump having a depression on a surface thereof, after other solder bumps around it are melted, a gap between the semiconductor package 300 and the external device 400 is further narrowed so that the solder bump having the depression may be sufficiently bonded to the connection terminal 410.

FIG. 4C illustrates a state in which a temperature reaches the melting point of the solder bumps 310 in the reflow process and the solder bumps 310 and the dummy solders 320 are both in a molten liquid phase. After the solder bumps 310 and the dummy solders 320 wet the connection terminal, the solder bumps 310 and the dummy solders 320 are cooled and the dummy solders 320 and the solder bumps 310 return to a solid state. The now solid dummy solders 320 and solder bumps 310 bond to the connection terminals 410 of the external device 400.

For the operation of the reflow processing using the dummy solder as described above, the melting point of the dummy solder must be lower than the melting point of the solder bumps. For example, in some embodiments the melting point of the dummy solder is 190 degrees Celsius or lower, and the melting point of the solder bumps 210 degrees Celsius or higher.

In some embodiments, the dummy solder is made of Sn—Bi—X (where X is Ag or Fe). The Bi may be 35 to 40 wt %, and the Ag or Fe may be 6 wt % or less, and may preferably be 3 wt % or less.

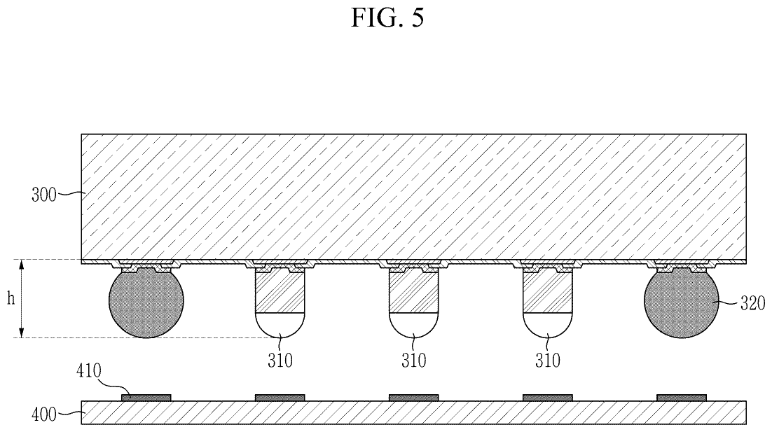

FIG. 5 illustrates an example of a semiconductor package 300 including dummy solders 320 having a different size from solder bumps 310 according to another embodiment of the present disclosure.

Connection terminals 410 and the solder bumps 310 provided on one surface of the semiconductor package 300 may be the same as those described in the embodiment of FIG. 4. However, unlike the solder bumps 310 shown in FIG. 4, the dummy solders 320 of FIG. 5 do not include a metal post between the dummy solder 320 and the UBM layers (not numbered).

Although the dummy solders 320 have a ball shape with a larger diameter than the solder bumps 310, a maximum height h of the dummy solders 320 from one surface of the semiconductor package 300 is preferably set to be the same as a maximum height of the solder bumps 310. Since the dummy solders 320 in the present embodiment are larger in size than the solder bumps 310, the force due to surface tension is relatively large when the dummy solders 320 are in the liquid molten state.

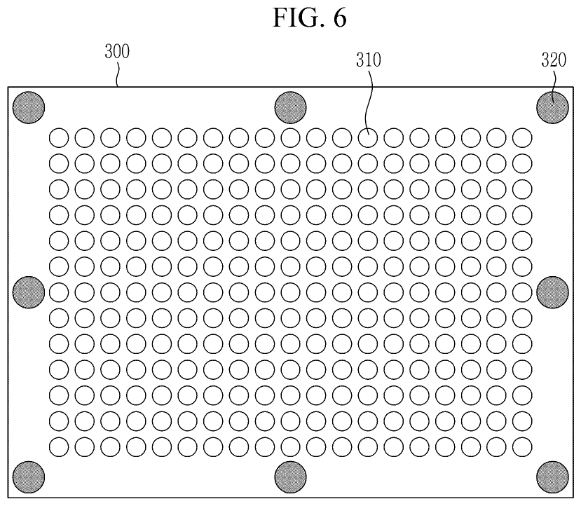

It may be preferable to dispose the ball-shaped dummy solders 320 to be point symmetrical about the center of an array of the solder bumps 310. FIG. 6 illustrates the disposition of the ball-shaped dummy solders 320 as an example. However, embodiments are not limited thereto, and those skilled in the art will understand that various dispositions including the disposition illustrated in FIG. 3A to FIG. 3D are possible.

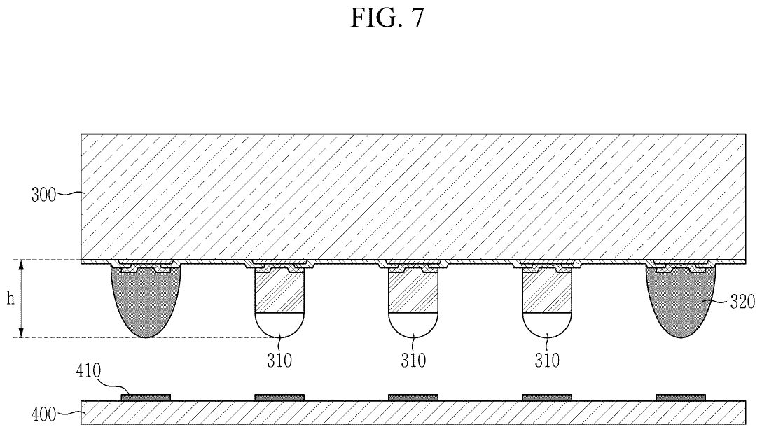

FIG. 7 illustrates an example of a semiconductor package including dummy solders 320 having a different shape from solder bumps 310 according to another embodiment of the present disclosure.

Connection terminals 410 on an external device 400 and solder bumps 310 provided on one surface of a semiconductor package 300 may be the same as those in the embodiment of FIG. 4 with the solder bumps 310 connected 5 to a UBM layer by a metal post. However, unlike the solder bumps 310, the dummy solders 320 do not include a metal post.

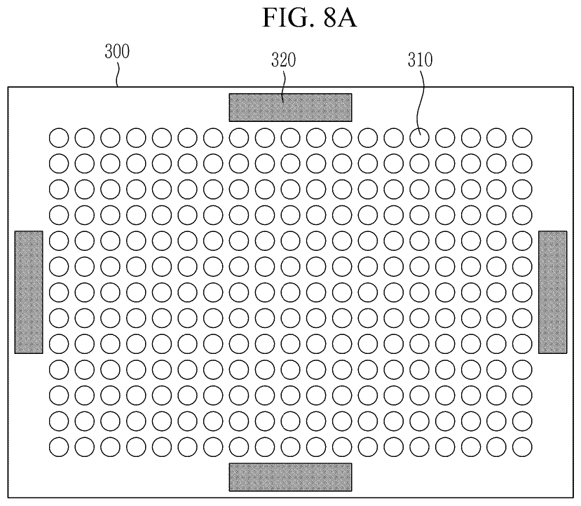

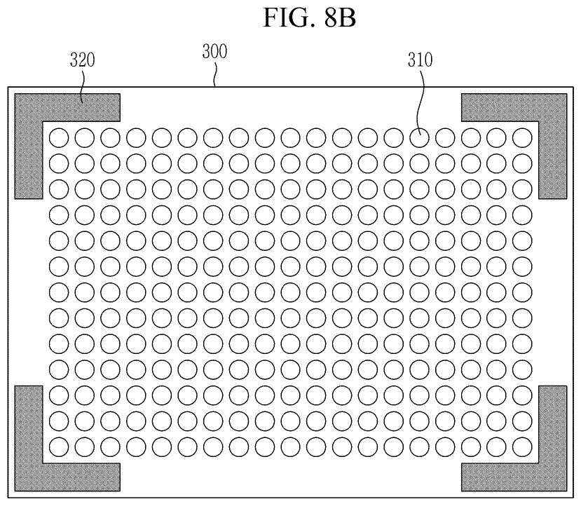

When viewed in a plan view such as the views shown in FIG. 8A and FIG. 8B, the dummy solders 320 form lines. The dummy solders 320 have a line shape, and a maximum height h of the dummy solders 320 from one surface of the semiconductor package 300 is preferably set to be the same as a maximum height of the solder bumps 310.

FIG. 8A and FIG. 8B illustrate examples in which line-shaped dummy solders 320 are disposed so as to be point symmetrical about the center of an array of the solder bumps 310.

In FIG. 8A, the line-shaped dummy solders 320 are disposed at four sides, respectively. The line-shaped dummy solder 320 may be provided by, for example, a method of printing solder paste at a corresponding position by using a stencil having a dummy solder disposition pattern. Although the dummy solders 320 shown in FIG. 8A have a rectangular shape, in some embodiments the line-shaped solders may have rounded ends.

In FIG. 8B, line-shaped dummy solders are disposed at four corners of the semiconductor package 300, respectively.

The disposition of the line-shaped dummy solders is not limited to those shown in FIGS. 8A and 8B and other arrangements are possible. For example, the line-shaped dummy solder may be disposed to surround a periphery of a solder bump array. In another example, when there is a space inside the solder bump array, the line-shaped dummy solder may be disposed in the space inside the solder bump array.

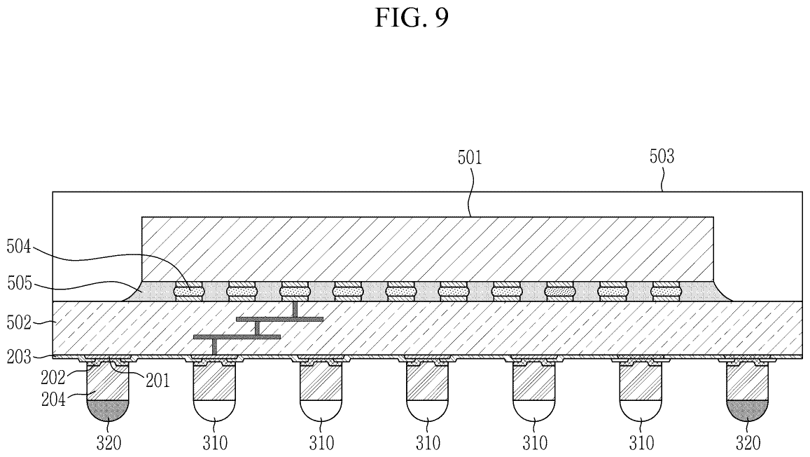

FIG. 9 schematically illustrates a cross-sectional view of a semiconductor package according to another embodiment of the present disclosure. This semiconductor package includes a semiconductor chip 501 and a chip carrier 502. Solder bumps 504 electrically connect the semiconductor chip 501 and the chip carrier 502 to each other. A space between the solder bumps 504 is filled with an underfill 505. The underfill 505 serves to insulate and protect the solder bumps 504.

A first side of the semiconductor chip 501 is mounted on a first surface of the chip carrier 502 and a second side of the semiconductor chip 501 is sealed by a resin mold 503 such as epoxy.

The chip carrier 502 includes connection terminals on a second surface thereof to connect the semiconductor chip 501 mounted on the first surface of the chip carrier 502 to an external device. The chip carrier 502 includes a via hole and a metal wire layer. The chip carrier 502 may be a package substrate or an interposer. The chip carrier 502 may be a substrate or board in which a semiconductor chip is mounted on a first surface thereof and at least two dummy solders and solder bumps for electrical connection to an external device are provided on a second surface thereof. The first surface, also referred to as an outer surface, of the chip carrier 502 may include a UBM layer 202 in contact with a metal pad 201 through the metal pad 201 and the passivation layer 203 for electrical connection to an external device, the metal post 204 provided on the UBM layer 202, and the solder bump 310 provided on the metal posts 204 are provided on the outer surface of the chip carrier 502. In addition, the dummy solder 320 having the same shape and size as the solder bump 310 is disposed at outside of a perimeter of an array of the solder bumps 310.

The disposition of the dummy solder 320 of FIG. 9 as viewed in a plan view may have various patterns as illustrated previously in FIG. 3A to FIG. 3D.

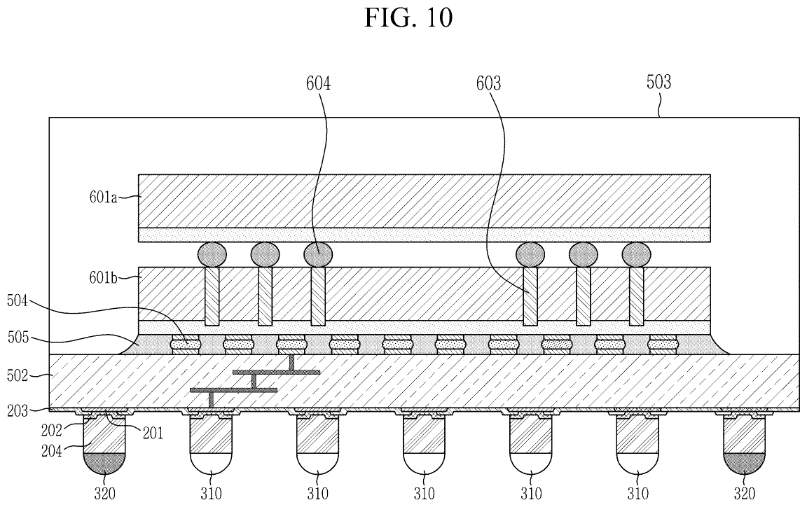

FIG. 10 schematically illustrates a cross-sectional view of a semiconductor package according to another embodiment of the present disclosure. This semiconductor package includes a first semiconductor chip 601a stacked on a second semiconductor chip 601b and a chip carrier 502.

The two stacked semiconductor chips 601a and 601b are connected by micro solder bumps 604. The second semiconductor chip 601b includes a conductive through hole 603, and the conductive through hole 603 transmits a signal to and from the first semiconductor chip 601a mounted thereon.

The semiconductor package according to the present embodiment may be a high bandwidth memory (HBM) package. For convenience, two stacked semiconductor chips are shown, but those skilled in the art will easily understand that embodiments can be applied to a package in which 4, 8, or 16 semiconductor chips or other quantities of semiconductor chips are stacked.

A surface of the second semiconductor chip 601b opposing the first semiconductor chip 601A is bonded to one surface of the chip carrier 502 by the solder bumps 504. The underfill 505 fills the space between the solder bumps 504. The stacked semiconductor chips 601a and 601b are protected from an external environment by the resin mold 503. For further description of the configurations of the chip carrier 502, the solder bumps 310, and the dummy solders 320, the embodiment of FIG. 9 may be referred to and detailed descriptions thereof are omitted with reference to FIG. 10.

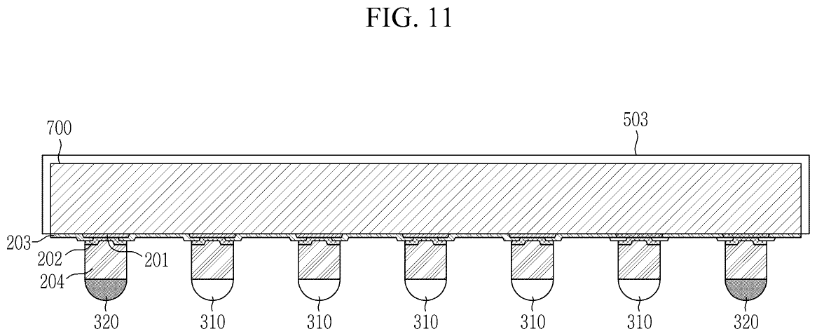

FIG. 11 shows a schematic configuration of a wafer level chip scale package (WLCSP) according to another embodiment of the present disclosure.

The metal pads 201 are provided on one surface of a semiconductor die 700. The passivation layer 203 entirely covers the one surface. In the present embodiment, the passivation layer 203 may have a two-layer structure including a die passivation layer and a repassivation layer stacked on each other. The UBM layers 202 penetrate the passivation layer 203 and contact the metal pads 201. The metal posts 204 are provided on UBM layers 202, and the solder bumps 310 and the dummy solders 320 are provided on the metal posts 204. The semiconductor die 700 is surrounded by the resin mold 503. In some embodiments, only four side surfaces of the semiconductor die 700 may be surrounded by the resin mold 503, or in other embodiments, the resin mold 503 may extend to the surface where the solder bumps 310 are provided.

In the embodiment of FIG. 9 to FIG. 11, the dummy solders 320 are shown as having the same shape and size as the solder bumps 310, but as described above, they may have a different shape or size therefrom.

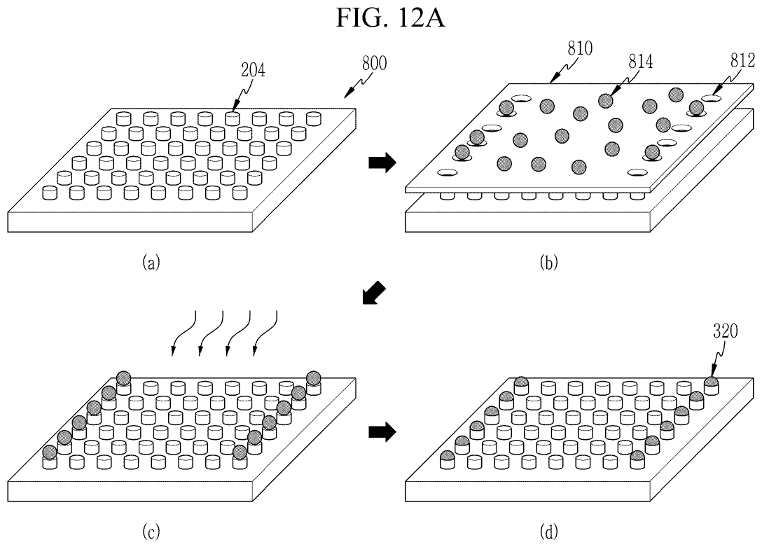

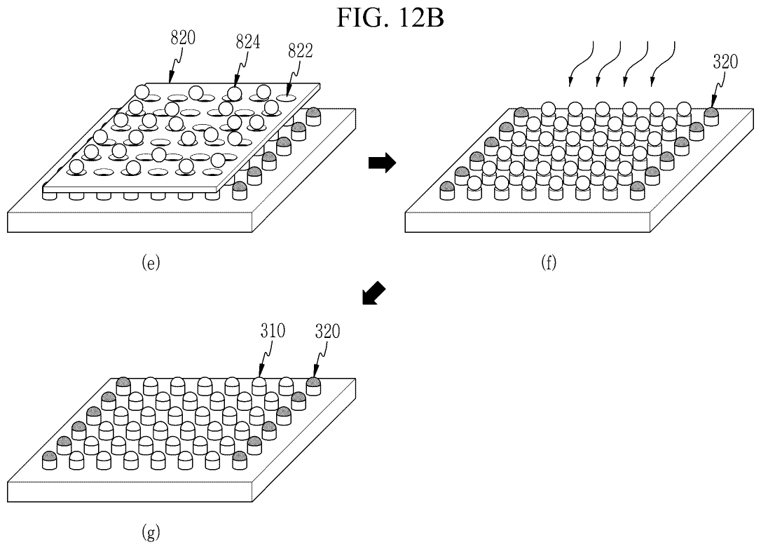

FIG. 12A and FIG. 12B schematically illustrate a manufacturing method of a semiconductor package according to an embodiment of the present disclosure. In the embodiment of FIG. 12A, the dummy solders 320 have the same shape and size as the solder bumps 310 and are all provided on the metal posts 204.

In step (a) of FIG. 12A, a semiconductor package 800 in which the metal posts 204 are provided on one surface thereof is provided. The semiconductor package 800 may be one of the semiconductor packages shown in FIG. 1, FIG. 9, FIG. 10, and FIG. 11, but is not limited thereto. A UBM layer and a metal pad are provided under each of the metal posts 240 (not shown). Some of the metal posts 240 are dummy metal posts provided for the dummy solders 320. The dummy metal posts can be connected to a ground or can be electrically independent of other normal metal posts.

In the embodiment of FIG. 12A, the dummy metal posts are disposed at both the left and right sides of the surface of the semiconductor package in the drawing. The process of providing connection terminals including the metal posts 204 on the one surface of the semiconductor package 800 is generally known and described previously, so a detailed description thereof is omitted.

In step (b) of FIG. 12A, a mask 810 is aligned on the semiconductor package 800. The mask 810 includes openings 812 that are sized to pass a solder ball of a plurality of solder balls. Positions of the openings 812 correspond to the dummy metal posts on the semiconductor package 800. Then, a plurality of the lower temperature solder balls 814 made of a solder material for dummy solder are placed on the mask 810, and vibration is applied to the mask 810 so that some of the plurality of solder balls 814 pass through the openings 812 of the mask 810 and onto the dummy metal posts. The plurality of solder balls 814 are made of a solder material having a lower melting point than solder balls 824 for forming solder bumps used in step (e) of FIG. 12B as will be described later. The solder balls 814 may be formed of Sn—Bi—X (where X is Ag or Fe).

In step (c) of FIG. 12A, the mask 810 is removed, and the solder balls 814 remain on the dummy metal posts. Then, a reflow process for forming solder bumps is performed to melt the solder balls 814 on the dummy metal posts. A temperature for the reflow process in this step is relatively lower than a temperature for the reflow process for forming the solder bumps of the solder balls 824 in step (f) of FIG. 12B.

FIG. 12A (d) shows a state in which the solder balls have melted from the reflow process performed in step (c) and have been cooled to form dummy solders 320. In the state shown in FIG. 12A (d), the dummy solders 320 adhere to the dummy metal posts.

Subsequently, in step (e) of FIG. 12B, a mask 820 having openings 822 sized to pass a solder ball of a plurality of solder balls 824 and corresponding to positions of normal metal posts is aligned on the semiconductor package 800. The plurality of solder balls 824 are provided on the mask 820, and vibration is applied to the mask 820 so that some of the solder balls 824 fall into the openings 822 and onto the normal metal posts. The solder balls 824 have a higher melting point than the solder balls 814 used in step (b) of FIG. 12A.

In step (f) of FIG. 12B, the mask 820 is removed, and the solder balls 824 remain disposed on the normal metal posts. Then, another reflow process is performed to melt the solder balls 824 on the normal metal posts to form solder bumps 310. A temperature for the reflow process in this step is relatively higher than a temperature for the reflow process in step (c) of FIG. 12A.

FIG. 12B (g) shows a state after the another reflow process has completed and the solder balls 824 have cooled, resulting in the solder bumps 310 and the dummy solders 320 being adhered on their respective metal posts 204. Thus, the steps shown in FIGS. 12A and 12B result in a solder bump array provided on one surface of the semiconductor package 800, and at least two dummy solders are disposed point-symmetrically about the center of the solder bump array.

After the solder bump array is provided on one surface of the semiconductor package 800, and at least two dummy solders are disposed point-symmetrically about the center of the solder bump array, the semiconductor package 800 is turned over to face the external device, and a reflow process for bonding the semiconductor package to the external device is performed. In this reflow process, the dummy solders 320 melt before the solder bumps 310 to generate contact pressure for the solder bumps 310.

FIG. 12A and FIG. 12B show a manufacturing method using the masks 810 and 820 and the solder balls 814 and 824, but other methods may be used to provide dummy solder and solder bumps on metal posts. The mask may be a stencil. In some embodiments, solder paste may be used instead of the solder balls. For example, the plurality of solder balls 814 may be replaced by a solder paste have a lower melting point compared to the plurality of solder balls 824 and/or the plurality of solder balls 824 may be replaced by a solder past having a higher melting point compared to the plurality of solder balls 814.

As another example of the manufacturing method, a method of forming a photoresist pattern, plating a solder material according to the pattern, and then forming a bump by a reflow process may be used.

As another example of the manufacturing method, a method of adsorbing the solder balls by using a vacuum adsorber equipped with the mask and then disposing the solder balls at a predetermined position may be used.

In the present embodiment, the manner in which the solder bumps and the dummy solder are provided on the metal post is described as an example, but it may be applied even when there is no metal post. In addition, in the present embodiment, the solder bump and the dummy solder have the same shape and size, but in other embodiments the solder bump and the dummy solder may have different shapes or sizes.

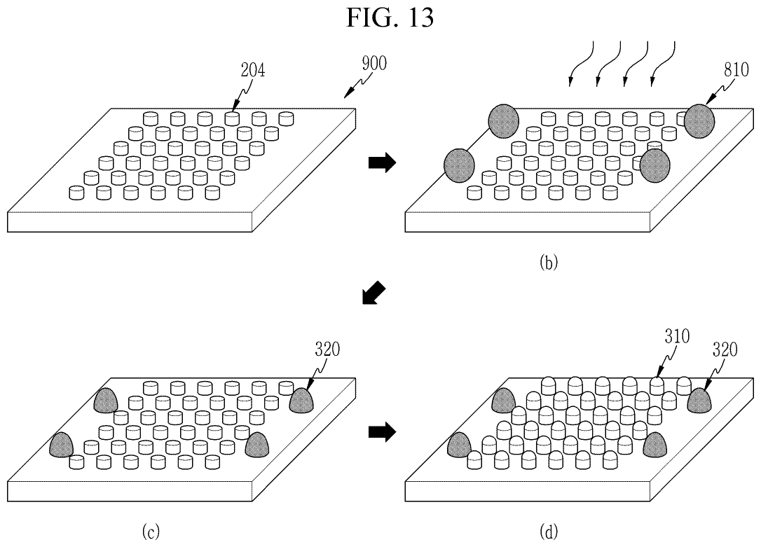

FIG. 13 shows an example of a manufacturing process of a semiconductor package 900 when a solder bump 310 and a dummy solder 320 have different shapes or sizes.

In step (a) of FIG. 13, a semiconductor package 900 in which a plurality of metal posts 204 are provided on one surface thereof is provided. Step (a) of FIG. 13 is similar to step (a) of FIG. 12A, but there is a difference in that no metal post is provided at the position at which the dummy solder is disposed. That is, a semiconductor package 900 does not include dummy metal posts. However, dummy metal pads (not shown) may be disposed on one surface of the semiconductor package 900 at positions at which dummy solders are disposed. The dummy metal pads may be connected to the ground and may be electrically isolated from other metal pads. The dummy metal pads may serve to maintain bonding force with the dummy solders when the dummy solders are disposed thereon.

In step (b) of FIG. 13, solder material 810 for forming the dummy solders is disposed near four corners of the semiconductor package 900, and a reflow process is performed to melt the solder material 810. The solder material 810 has a lower melting point than the solder material used to form the solder bump 310. In the present embodiment, the solder material 810 has a ball shape and is disposed point-symmetrically about the center of the solder bump array. The size or shape of the solder material 810 should be selected so that the dummy solders 320 and the solder bumps 310 will have the same height from one surface of the semiconductor package 900.

FIG. 13 (c) shows a state in which the solder material 810 has been melted in a reflow process and changed into the shape of the dummy solders 320. Thereafter, the same process as step (e) and step (f) of FIG. 12B is performed.

FIG. 13 (d) shows a state in which the solder material has been reflowed to change into the solder bumps 310, and the dummy solders 320 are finally formed. The dummy solders 320 have different sizes from the solder bumps 310, but have the same maximum height from the surface of the semiconductor package 900.

In the present embodiment, the dummy solder has a ball shape, but those skilled in the art will understand that a semiconductor package having a dummy solder of a line shape may be manufactured by disposing solder paste into a line shape.

Other methods for forming dummy solder and solder bumps may be used. For example, in some embodiments, the order of providing the solder balls 814 and 824 may be reversed, such that the solder balls having a higher melting temperature may be provided on a metal post and undergo a reflow process prior to a solder ball 814 having a lower melt temperature being disposed on dummy post and undergoing a reflow process. However, in that case a dummy solder having a relatively low melting point is formed first, and then a solder bump having a relatively high melting point is formed as shown in FIGS. 12 and 13, the reflow process for forming bumps is applied only once for the solder bumps. In a case where the solder bump is formed first, the solder bump is once again exposed at a high temperature during the reflow process of dummy solder, even if it doesn't undergo reflowing itself, and this may further promote IMC growth. The largely grown IMC is a factor in connection failure.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a main body including at least one semiconductor chip;
a plurality of connection terminals provided on a surface of the main body;
a solder bump array disposed on the plurality of connection terminals and including a plurality of solder bumps configured to electrically connect each of the connection terminals to a respective connection terminal of a device by a soldering process; and
at least one dummy solder connected to the surface of the main body and disposed point-symmetrically about a center of the solder bump array,
wherein the plurality of solder bumps of the solder bump array have a first melting point, and the at least one dummy solder has a second melting point lower than the first melting point so that when heated, the at least one dummy solder melt before the plurality of solder bumps and generate a force in a direction in which the plurality of solder bumps contact connection terminals of the device by surface tension during a soldering process.

2. The semiconductor package of claim 1, wherein
the at least one dummy solder is disposed at an outside of a perimeter of the solder bump array.

3. The semiconductor package of claim 2, wherein
the surface of the main body has a quadrangular shape, and the at least one dummy solder includes a plurality of dummy solders disposed at each of four corners of the quadrangular shape of the surface of the main body.

4. The semiconductor package of claim 2, wherein
the surface of the main body has a quadrangular shape, and the at least one dummy solder includes a plurality of dummy solders disposed at each of four sides of the quadrangular shape of the surface of the main body.

5. The semiconductor package of claim 1, wherein
the at least one dummy solder comprises a plurality of dummy solders, a shape and size of which is the same as a shape and size of a solder bump of the plurality of solder bumps.

6. The semiconductor package of claim 5, wherein:
each of the connection terminals includes a connection pad and a conductive metal post protruding from the connection pad, and each of the solder bumps is disposed on a respective conductive metal post; and
a plurality of dummy connection terminals having the same structure as the connection terminals are disposed on the surface of the main body at a positions corresponding to the plurality of dummy solders, and each of the plurality of dummy solders is disposed on a respective metal post of the dummy connection terminals.

7. The semiconductor package of claim 1, wherein
each dummy solder of the plurality of dummy solders has a shape or size that is different from a shape or size of a solder bump of the plurality of solder bumps, and a maximum height of each dummy solder of the plurality of dummy solders from the surface of the main body is the same as a maximum height of the solder bump.

8. The semiconductor package of claim 7, wherein
each dummy solder of the plurality of dummy solders is provided in a ball or line shape.

9. The semiconductor package of claim 1, wherein
the at least one dummy solder includes at least one first dummy solder bump having the same shape and size as the shape and size of the solder bumps of the plurality of solder bumps and at least one second dummy solder bump having a shape or size that is different from the shape or size of the solder bumps of the plurality of solder bumps.

10. The semiconductor package of claim 1, wherein
the main body further includes a substrate or an interposer including a first surface and a second surface opposite the first surface and the at least one semiconductor chip is mounted on the first surface and the plurality of solder bumps and the at least one dummy solder are disposed on the second surface.

11. The semiconductor package of claim 1, wherein
the surface of the main body is a surface of the at least one semiconductor chip.

12. The semiconductor package of claim 1, wherein
the first melting point is 210° C. or more, and the second melting point is 190° ° C. or less.

13. The semiconductor package of claim 12, wherein
the dummy solder is made of Sn—Bi—X, where X is Ag or Fe.

14. The semiconductor package of claim 13, wherein
a Bi content is 35 to 40 wt %, and an Ag or Fe content is 6 wt % or less.

15. A semiconductor package comprising:
at least one semiconductor chip;
a chip carrier including a first surface to which the at least one semiconductor chip is bonded; and
a resin mold that seals the at least one semiconductor chip and the first surface with a resin material,
wherein:
the chip carrier includes a redistribution layer, a plurality of first connection terminals on the first surface for connection with the at least one semiconductor chip, and a plurality of second connection terminals on a second surface opposite to the first surface for connection with a device;
the plurality of first connection terminals are electrically connected to terminals of the semiconductor chip;
each of the second connection terminals includes a connection pad connected to the redistribution layer and a metal post disposed on the connection pad, and a solder bump having a diameter of 10 to 30 μm is disposed on each metal post;
the chip carrier includes at least two dummy solders at outside of a perimeter of the plurality of second connection terminals on the second surface; and
the solder bumps have a first melting point, and the at least two dummy solders have a second melting point lower than the first melting point so that when heated, the at least two dummy solders melt before the solder bumps to generate a force in a direction in which the plurality of solder bumps contact the connection terminals of the device by surface tension during a soldering process.

16. The semiconductor package of claim 15, wherein
the chip carrier further includes a plurality of dummy connection terminals having the same structure as the second connection terminals, wherein the plurality of dummy connection terminals are located outside of the plurality of second connection terminals on the second surface and are arranged point-symmetrically, and
the at least two dummy solders have the same size and shape as the solder bumps and are provided on metal posts of the dummy connection terminals.

17. A manufacturing method of a semiconductor package, comprising:
attaching at least one semiconductor chip to a first surface of a chip carrier and providing a plurality of connection terminals for electrical connection with another device on a second surface opposite to the first surface, wherein each of the connection terminals includes a connection pad and a metal post disposed on the connection pad;
disposing a first solder material to be point symmetrical about a center of the plurality of connection terminals;
providing a plurality of dummy solders by performing a first reflow process on the first solder material with a first maximum temperature;
disposing a second solder material onto metal posts of the plurality of connection terminals; and
providing a plurality of solder bumps by performing a second reflow process on the second solder material with a second maximum temperature,
wherein a melting point of the first solder material is lower than that of the second solder material, and the first maximum temperature is lower than the second maximum temperature.

18. The manufacturing method of the semiconductor package of claim 17, wherein:
the providing of the plurality of connection terminals includes further providing a plurality of dummy connection terminals disposed point-symmetrically about the center of the plurality of connection terminals on the second surface, and the plurality of dummy connection terminals have the same structure as the plurality of connection terminals;
the disposing of the first solder material includes:
covering the second surface with a first mask having openings at positions corresponding to the plurality of dummy connection terminals; and
disposing the first solder material on the metal posts of the dummy connection terminals through the openings of the first mask; and
the disposing of the second solder material onto the metal posts of the plurality of connection terminals includes:
covering the second surface with a second mask having openings at positions corresponding to the metal posts of the plurality of connection terminals; and
disposing the second solder material on the metal posts of the connection terminals through the openings of the second mask.

19. The manufacturing method of the semiconductor package of claim 17, wherein
the disposing of the first solder material includes
disposing the first solder material in a ball or line shape on the second surface so as to be disposed point-symmetrically about the center of the plurality of connection terminals.

20. The manufacturing method of the semiconductor package of claim 17, wherein
the plurality of dummy solders are disposed outside of a perimeter of the plurality of solder bumps.
